(19) United States
(12) Patent Application Publication
(10) Pub. No.: US 2009/0137069 A1
(43) Pub. Date: May 28, 2009

(54) Chip packaging process including simpification and mergence of burn-in test and high temperature test

(75) Inventors: Li-Chih Fang, Hsinchu (TW); Wen-Jeng Fan, Hsinchu (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/987,235

(22) Filed: Nov. 28, 2007

(51) Int. Cl. H01L 21/66

(52) U.S. Cl. 438/15; 257/E21.521

(57) ABSTRACT

A chip packaging process integrates a burn-in test or a high temperature test to simplify overall packaging and testing process flow. One or more chips are disposed on one or more units of a substrate strip where the substrate strip has a plurality of electrical open sections at the plating lines to electrically isolate the external pads between different units. After electrical connection and encapsulation, a burn-in test is executed at the same time of a post mold curing step, with a high-temperature testing if necessary. Therefore, the chips on the substrate strip has been gone through the burn-in test during the encapsulant is completely cured at the post mold curing step and the burn-in test is finished before the singulation step to reduce the overall testing time.

### FIELD OF THE INVENTION

The present invention relates to chip packaging processes, especially to chip packaging processes integrating burn-in test with high temperature test to simplify overall packaging and testing process flow.

### BACKGROUND OF THE INVENTION

The conventional manufacture of IC (integrated circuit) chip packages primarily divide into two major processes where one is the chip packaging process to package IC chips into BGA (Ball Grid Array) type chip packages or the other types of packages and the other is the package-level testing to separate failed chip packages from good ones with speed sorting. The conventional chip packaging process is to dispose a plurality of IC chips on a substrate strip until ball placement. After singulation, the packaged chips on a substrate strip become individual chip packages. Then package-level testing is followed by depositing individual chip packages into testing sockets for final test to screen failed packages from good ones with speed sorting. Especially, since memory chip packages are mass-production IC commodities with standard specifications, therefore, yields and productivities are very important to increase revenues and profits. How to lower the overall manufacture cost, including packaging and testing, becomes the first priority.

The conventional packaging process primarily comprises the steps as shown in FIG. 1. First of all, step 11 of “wafer lapping” is performed to assure that all IC chips have the same thickness within the specifications. Step 12 of “die sawing” is performed to separate a plurality of chips on a wafer into a plurality of individual chips. Then from step 13 to step 17, chip packaging process is performed on a substrate strip, not shown in the figure. Finally, until step 18 of “package singulation”, one or more individual packages are formed. After step 14 and step 15, a plurality of chips are electrically connected to the substrate strip and are encapsulated by an encapsulant where the encapsulant is thermal-setting. After PMC (post mold curing) step 16, the encapsulant is completely cured and becomes stable. Normally, PMC step 16 is performed by putting a plurality of substrate strips into an oven to cure the encapsulant under specific temperatures with specific times according to the physical properties of the corresponding encapsulant. Then, after step 17 of “depositing external terminals” and step 18 of “package singulation”, one or more individual chip packages, such as BGA packages, are separated from the substrate strip. However, step 17 of “depositing external terminals” can be eliminated if Land Grid Array (LGA) packages are manufactured.

Furthermore, the conventional package-level testing process for chip packages includes a burn-in test to screen those “early failure” chip packages when the manufactured chip packages is memory devices or includes memory cells. The conventional package level testing process primarily comprises the steps as shown in FIG. 2. In step 21 of “first high-temperature storage”, one or more chip packages are disposed in a high-temperature environment such as 80° C. for 100 seconds to screen all the failed chip packages. Then, in step 22 of “burn-in test”, one or more chip packages are individually disposed in the corresponding test sockets of a burn-in board and the contact pins in the burn-in sockets will make electrically connections with the external terminals of the chip packages with input biases under high temperatures to simulate memory chip operating under a long period of time to screen “early failure” memory chips to avoid customer complaints during early operation periods. Then, step 23 of “low-temperature storage” and step 24 of “second high-temperature storage” are executed for speed sorting the chip packages. Therefore, burn-in test is a crucial step during the conventional package level testing of memory chip packages, however, the burn-in time is quite long such as 24 hours under 125° C. The only thing to reduce the burn-in cycle time is to burn-in a plurality of chip packages in each burn-in oven, but the increase of burn-in ovens are essential.

### SUMMARY OF THE INVENTION

The main purpose of the present invention is to provide a chip packaging process integrating burn-in test to simplify overall packaging and testing process flow, so that testing time of memory chip packages is reduced leading to shorter overall manufacture cycle time.

The second purpose of the present invention is to provide a chip packaging process integrating burn-in test to simplify overall packaging and testing process flow. By substrate-level bum in test, the post mold curing step and burn-in test can be integrated and executed in single equipment to reduce capital investment of packaging and testing and to reduce damages of external terminals during testing processes.

According to the present invention, a chip packaging process integrating burn-in test is revealed. Firstly, one or more chips are provided, then, the chips are attached to one or more units of a substrate strip where each unit has a die-attaching surface and a corresponding SMT surface, moreover, a plurality of external pads are disposed on the SMT surface. Then, the chips are electrically connected to the corresponding units. Then, an encapsulant is formed on the die-attaching surface of the substrate strip to encapsulate the chips. Then, a post mold curing (PMC) step is executed to completely cure the encapsulant, meanwhile, a substrate-level burn-in test, even a high-temperature test, is executed where the external pads of the substrate strip are electrically contacted by a plurality of probing terminals of a burn-in probing board to create electrical connections to the chips for burn-in. Moreover, before the PMC step, the substrate strip has a plurality of electrical open sections at the plating lines so that the external pads between different units are electrically isolated. Finally, a step of package singulation is executed, the units including encapsulated chips are separated to form individual chip packages by sawing the substrate strip.

### DESCRIPTION OF THE DRAWINGS

FIG. 1 shows a conventional chip packaging process flow.

FIG. 2 shows a conventional testing process flow for chip packages.

FIG. 3 shows a chip packaging process flow according to the present invention.

FIGS. 4A to 4C show the cross-sectional views of chips for the chip packaging process during steps 31 and 32 shown in FIG. 3 according to a preferred embodiment of the present invention.

FIGS. 5A to 5F show the cross-sectional views of a substrate strip for the chip packaging process during steps 33 and 38 shown in FIG. 3 according to a preferred embodiment of the present invention.

FIG. 6 shows a testing process flow for the chip packages fabricated by the chip packaging process of FIG. 3 according to a preferred embodiment of the present invention.

FIG. 7 shows a partially enlarged view of electrical open sections at the plating lines at the unit peripheries of the substrate strip according to a preferred embodiment of the present invention.

FIG. 8 shows a partially enlarged view of electrical open sections at the plating lines at the unit center of the substrate strip according to another preferred embodiment of the present invention.

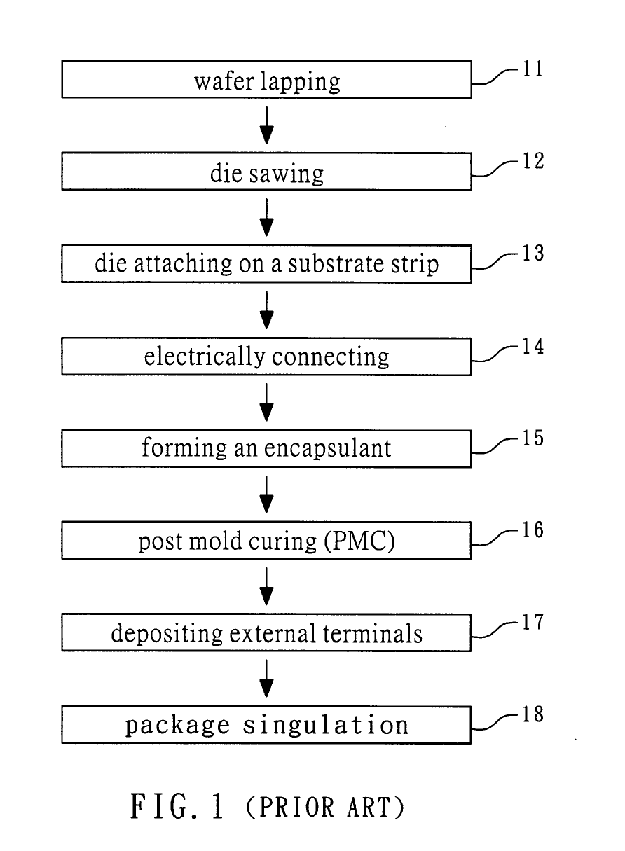

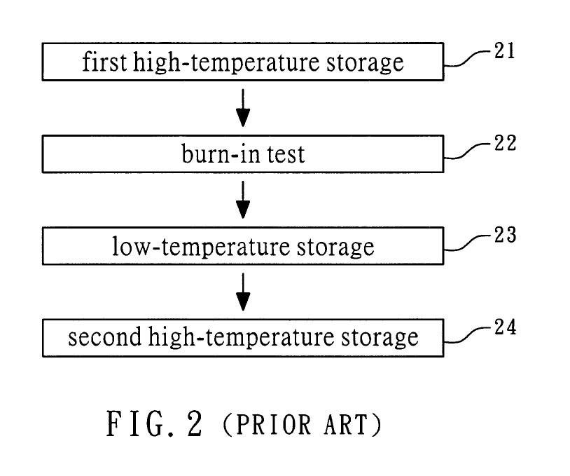

### DETAIL DESCRIPTION OF THE INVENTION

Please refer to the attached drawings, the present invention will be described by means of embodiment(s) below.

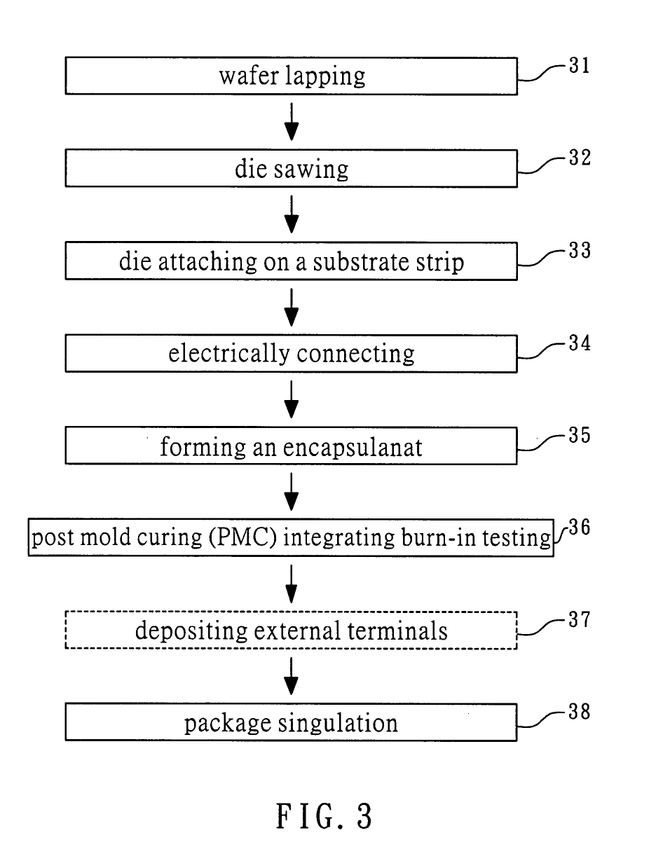

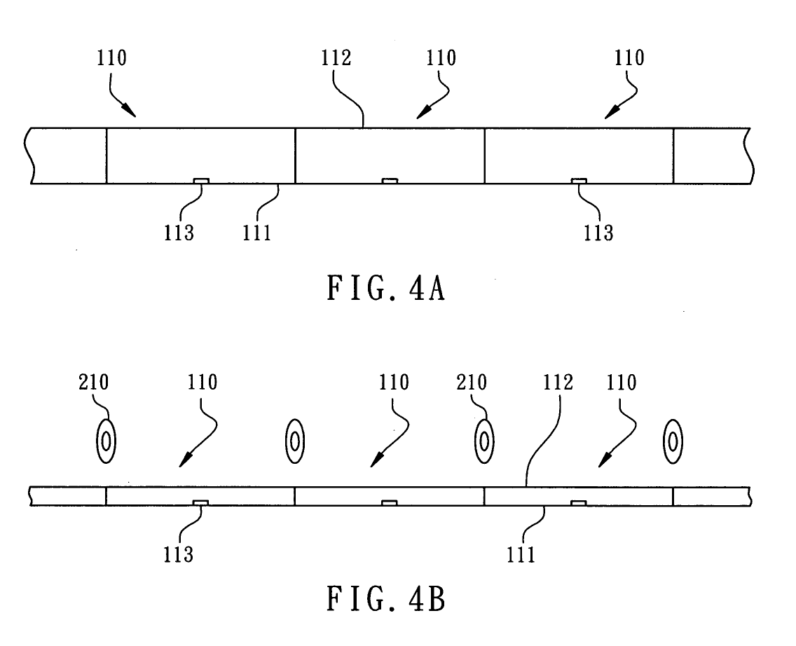

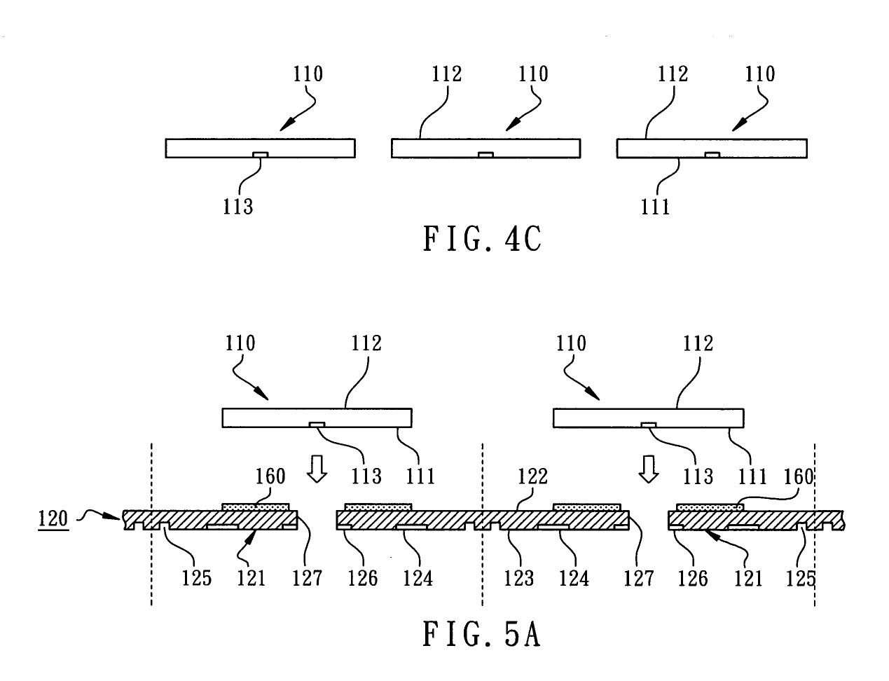

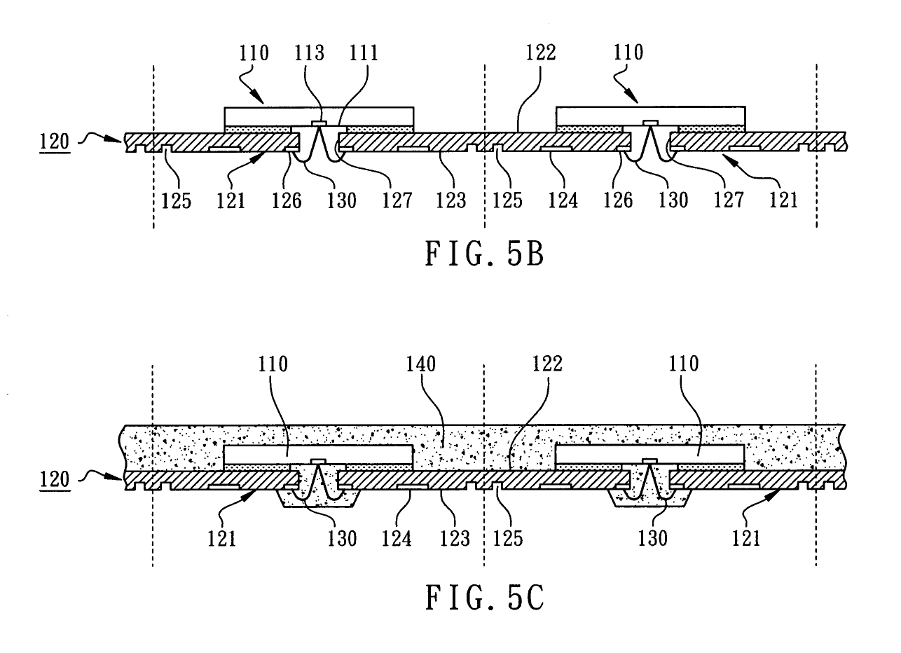

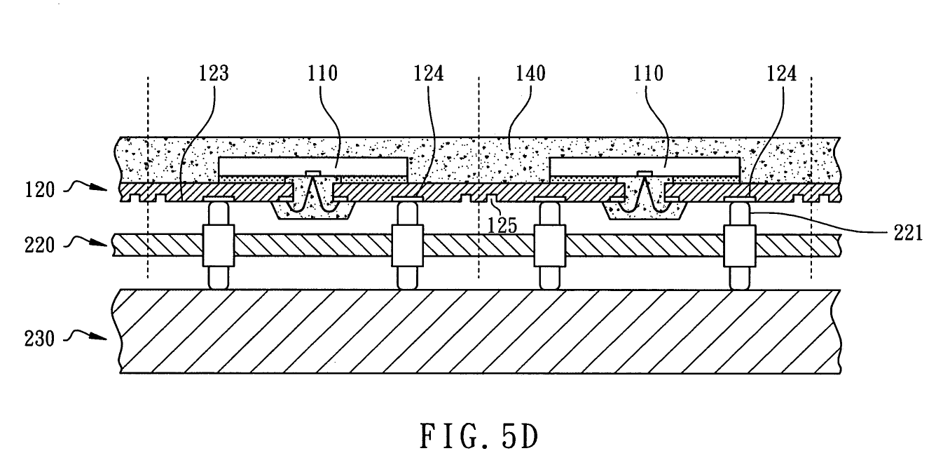

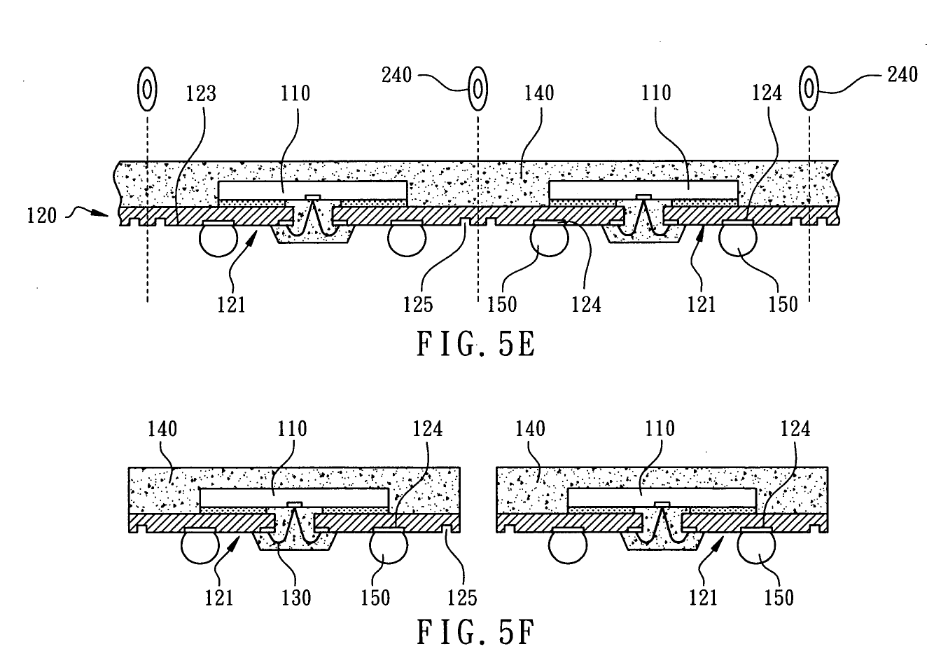

According to a preferred embodiment of the present invention, a chip packaging process integrating burn-in test is illustrated as shown in FIG. 3, which primarily comprises the following steps of: step 31 of “wafer lapping”, step 32 of “die sawing”, step 33 of “die attaching on a substrate strip”, step 34 of “electrically connecting”, step 35 of “forming an encapsulanat”, step 36 of “post mold curing (PMC) integrating burn-in testing”, and step 38 of “package singulation”. The process may further include step 37 of “depositing external terminals”, which is preferable but not necessary. The detail description is as follows as shown from FIG. 4A to FIG. 4C and from FIG. 5A to FIG. 5F.

Firstly, before the step 31 of “wafer lapping”, a wafer is provided can be shown in FIG. 4A. The wafer comprises a plurality of chips 110 (or called dies) each having an active surface 111 and a corresponding back surface 112. Memory blocks, bonding pads, and passivation, or various integrated circuits (not shown in the figure) are formed on the active surface 111 corresponding to each chip 110. Normally, the memory blocks are DRAM such as DDR I, DDR II, DDR III, or even DDR IV.

The step 31 of “wafer lapping” can be shown in FIG. 4B, the back surface 112 of the wafer is ground to thin the wafer to keep the chips 110 with a uniform thickness ranged from 0.5 mil to 12 mils for high-density chip stacking, or thinner packages, or other applications.

Then, step 32 of “die sawing” is executed. As shown in FIG. 4C, a plurality of individual chips 110 are formed by sawing the lapped wafer with a sawing tool 210, as shown in FIG. 4B.

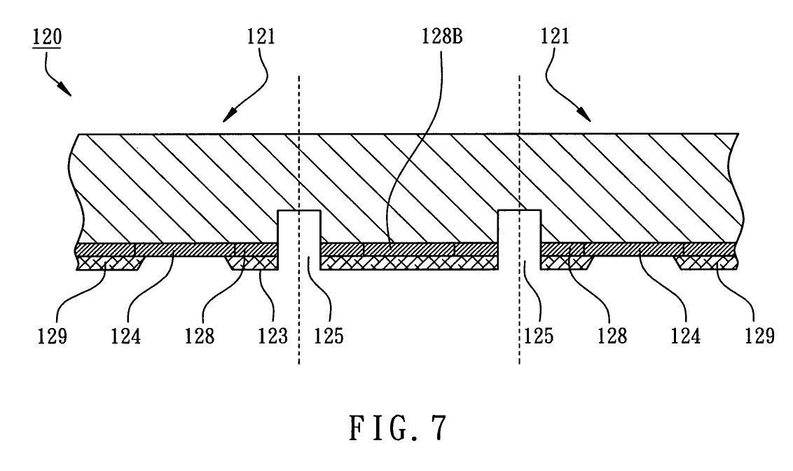

Next, steps 33 to 38 including burn-in test are executed on a substrate strip as shown from FIG. 5A to FIG. 5F. Step 33 of “die attaching on a substrate strip” can be shown in FIG. 5A and FIG. 5B, where one or more chips 110 are individually attached to one or more units 121 of a substrate strip 120 where a plurality of units 121 can be ranked as a matrix. Each unit 121 has a die-attaching surface 122 and a corresponding SMT (Surface Mount Technology) surface 123, where the die-attaching surface 122 is an inner surface for chip mounting and encapsulation, the SMT surface 123 is an external surface for package mounting. In the present embodiment, the active surface 111 of the chip 110 is attached to the corresponding die-attaching surface 122 by a die-attaching material 160 such as PI tape or B-stage adhesive. A plurality of external pads 124 are disposed on the SMT surface 123. In the present embodiment, the described chip package is a window type BGA (Ball Grid Array) package. Each unit 121 further has a wire-bonding slot 127 and a plurality of bonding fingers 126 adjacent to the wire-bonding slot 127 where a plurality of bonding pads 113 on the active surface I11 of the chip 110 are aligned and exposed from the wire-bonding slot 127 of the substrate strip 120 (as shown in FIG. 5B). The bonding pads 113 are located at the center of the active surface 111 of the chip 110 and are linearly arranged in one or more rows as chip electrical terminals where only one bonding pad 113 can be seen from the cross section of the chip 110 after the die-attaching step 33 as shown in FIG. 5B. Moreover, the bonding pads 113 can be linearly arranged in one single row or in two rows or in multiple rows. As shown in FIG. 5A again, before the PMC step 36, the substrate strip 120 has a plurality of electrical open sections 125 to break the plating lines so that the external pads 124 between different units 121 are electrically isolated. The electrical open sections 125 in the substrate strip 120 can be a slot or multiple holes which are defined by the solder mask or by direct punching. As shown in FIG. 7, to be a more specific description of the present embodiment, the electrical open sections 125 are formed at the peripheries of each unit 121 on the SMT surface 123. The substrate strip 120 is covered by a solder mask 129 on the SMT surface 123 including the traces except the external pads 124 which are not covered by the solder mask 129 and are exposed from the SMT surface 123. Each substrate strip 120 has a plurality of remaining plating lines 128 located at the peripheries of each unit 121 where one ends of the remaining plating lines 128 are cut to expose from the electrical open sections 125. The detail description above is just a more specific explanation of the present embodiment but the implementations of the present invention will not be limited. Moreover, the implemented packages of the present invention will not be limited in window-type BGA only but also can be implemented in LGA, QFN, FBGA, FCFBGA or PBGA, etc.

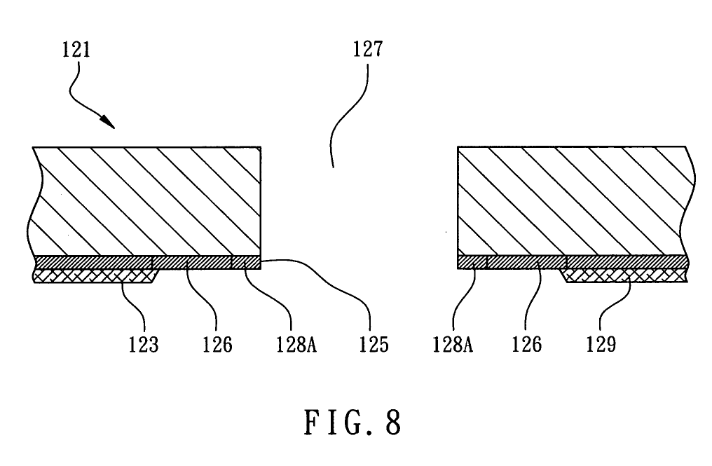

As shown in FIG. 8, another embodiment shows the electrical open sections 125 can be formed in the corresponding wire-bonding slot 127 of the units 121 where the plating lines are cut to form exposed ends while forming the wire-bonding slot 127. A plurality of remaining plating lines 128A are formed at the peripheries of the wire-bonding slot 127 so that the bonding fingers 126 connecting the external pads 124 between different units 121 are electrically isolated. In a different embodiment, the remaining plating lines can be completely removed to avoid burr issues.

Then, step 34 of “electrically connecting” can be shown in FIG. 5B, the chips 110 are electrically connected to the corresponding units 121 by a plurality of bonding wires 130. In the present embodiment, the bonding wires 130 is formed by wire-bonding technology to connect the bonding pads 113 of the chip 110 to the bonding fingers 126 of the substrate strip 120 on the SMT surface 123 by passing through the wire-bonding slots 127.

Then, as shown in FIG. 5C, encapsulation step 35 is executed to form an encapsulant 140 on the substrate strip 120 by transfer molding. In the present embodiment, the encapsulant 140 is formed on the die-attaching surface 122 and in the wire-bonding slots 127 of the substrate strip 120. The encapsulant 140 encapsulates the chips 110 and the bonding wires 130 to avoid the impact of moisture, heat, and electrical interference to enhance product reliability. The encapsulant 140 is extruded from the SMT surface 123 along the wire-bonding slots 127 to completely encapsulate the bonding wires 130.

Then, as shown in FIG. 5D, the PMC step 36 is executed; meanwhile, the encapsulant 140 is completely cured and a burn-in test is finished at the substrate level. The encapsulated substrate strip 120 is clamped with a probing board 220 and a burn-in board 230 and is disposed into a burn-in oven for burn-in test under high temperature environment. Therefore, the burn-in test is executed at the same time as the post mold curing (PMC) process, that is to say, the chips 110 are passed through a substrate level burn-in test at the same time of complete curing of the encapsulant 140. In PMC step 36, the external terminals 150 (as shown in FIG. 5E) are not yet disposed on the external pads 124 of the substrate strip 120. A plurality of probing terminals 221 of the burn-in probing board 110 directly and electrically contact to the external pads 124 of the substrate strip 120. Moreover, the probing terminals 221 of the probing board 110 also electrically connect to the burn-in board 230. In PMC step 36, the curing time should be appropriately extended to completely cure the encapsulant 140 and to effectively achieve burn-in test. The substrate strip 120, for example, is placed in the oven at 120° C. for more than six hours and an electrical current is input from the burn-in board 220 through the probing board 230 and through the external pads 124 to the memory chips 110 on the substrate strip 120 to apply an appropriate voltage to the memory chips 110. Therefore, after the PMC step 36, the encapsulant 140 is completely cured, at the same time, the “early failure” memory chips 110 on the substrate strip 120 are stressed at high biases under high temperatures.

Preferably, the above described PMC step 36 further comprises a high temperature storage test which can be executed to further enhance to screen the failed packages.

In the present embodiment, without any limitations, the terminal-depositing step 37 can be further executed after PMC step 36 and before step 38 of package singulation. As shown in FIG. 5E, when the terminal-depositing step 37 is executed, a plurality of external terminals 150 are deposited on the external pads 124 of the substrate strip 120. In the present embodiment, the external terminals 150 include a plurality of solder balls to form a BGA package. Since the PMC step 36 including burn-in test is executed before the terminal-depositing step 37, therefore, the external terminals 150 will not experience in a high-temperature environment for a long period of time during the burn-in test so that the external terminals 150 will have a better durability and bonding strengths. Using solder balls as an example, solder balls without experiencing high-temperature burn-in test will not form inter-metallic compound (IMC) embrittlement leading to fault soldering or ball dropping. Moreover, the solder balls will not be contacted and scrubbed during burn-in test leading to solder ball damages or missing.

Finally, the package singulation step 38 is executed as shown in FIG. 5E and FIG. 5F. As shown in FIG. 5F, a plurality of individual chip packages going through burn-in test are formed by sawing the scribe lines at the peripheries of the units 121 with the encapsulated chips 110 by a sawing tool 240 as shown in FIG. 5E. The sawing tool 240 can saw through the substrate strip 120 and the encapsulant 140 at the same time.

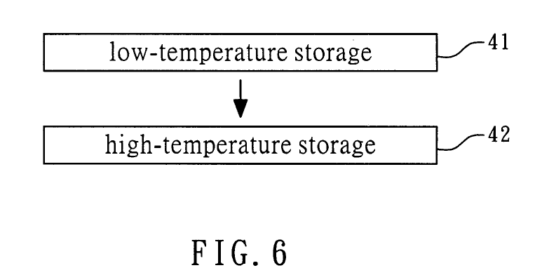

The chip packaging process is implemented to simplify overall packaging and testing process flow according to the present invention. As shown in FIG. 6, the sequent testing process for the chip packages as shown in FIG. 5F don't need to go through a complete burn-in test again except step 41 of “low-temperature storage” and step 42 of “high-temperature storage”. After going through final test, the failed memory chip packages will be screened and the good memory chip packages will be speed-sorted. Therefore, the overall testing time for the memory chip packages are greatly reduced leading to shorter overall packaging and testing cycles.

The above description of embodiments of this invention is intended to be illustrative and not limiting. Other embodiments of this invention will be obvious to those skilled in the art in view of the above disclosure.

What is claimed is:

1. A chip packaging process comprising:
providing one or more chips;
depositing the chips on one or more units of a substrate strip, each unit having a die-attaching surface and a corresponding SMT surface, a plurality of external pads formed on the SMT surface;
electrically connecting the chips to the corresponding units;
forming an encapsulant on the substrate strip to encapsulate the chips;
executing a post mold curing step to completely cure the encapsulant, meanwhile, executing a burn-in testing step where the external pads of the substrate strip are electrically contacted by a plurality of probing terminals of a burn-in probing board, where the substrate strip has a plurality of electrical open sections at the plating lines before the post mold curing step to electrically isolate the external pads between different units; and
executing a singulation step to form a plurality of individual chip packages each including a unit and the encapsulated chip by sawing the substrate strip.

2. The chip packaging process as claimed in claim 1, wherein the post mold curing step further includes a high-temperature storage test executed at the same time.

3. The chip packaging process as claimed in claim 1, further comprising the step of depositing a plurality of external terminals on the external pads of the substrate strip after the post mold curing step and before the singulation step.

4. The chip packaging process as claimed in claim 3, wherein the external terminals include a plurality of solder balls.

5. The chip packaging process as claimed in claim 1, wherein the electrical open sections are formed at the peripheries of the units on the SMT surface.

6. The chip packaging process as claimed in claim 1, wherein the electrical open sections are formed within one or more wire-bonding slots of the units.

7. The chip packaging process as claimed in claim 1, wherein each unit further has a wire-bonding slot and a plurality of bonding fingers adjacent to the wire-bonding slot, the chip has a plurality of bonding pads aligned in and exposed from the wire-bonding slot, moreover, a plurality of bonding wires are formed to connect the bonding pads with the bonding fingers during the electrically connecting step.

8. The chip packaging process as claimed in claim 1, wherein the encapsulant is sawed at the same time of sawing the substrate strip.

9. The chip packaging process as claimed in claim 1, wherein the electric open sections are formed before the die-attaching process.

10. The chip packaging process as claimed in claim 1, wherein the electrical open sections are formed after forming the encapsulant.
